(19) United States
(12) Patent Application Publication
(10) Pub. No.: US 2006/0038257 A1
(43) Pub. Date: Feb. 23, 2006

(54) Semiconductor device which includes an inductor therein and a manufacturing method thereof

(76) Inventor: Noritaka Anzai, Tokyo (JP)

Correspondence Address: VOLENTINE FRANCOS, P.L.L.C.;One Freedom Square, Suite 1260, 11951 Freedom Drive, Reston, VA, 20191, US

(21) Appl. No.: 11/172,825

(22) Filed: Jul. 5, 2005

(30) Foreign Application Priority Data
Aug. 19, 2004 (JP) 239305/2004

(51) Int. Cl. H01L 29/00

(52) U.S. Cl. 257/531

(57) ABSTRACT

A semiconductor device includes a semiconductor substrate having a principal surface in which a semiconductor integrated circuit is included and a spiral inductor disposed over the principal surface of the semiconductor substrate so as to be coupled to the semiconductor integrated circuit. A region occupied by the spiral inductor is an inductor region. The semiconductor device further includes a shielding film disposed between the principal surface of the semiconductor substrate and the spiral inductor. The shielding film includes a plurality of openings which radially extend in the shielding film from a middle of the inductor region toward a periphery of the inductor region. Alternatively, the semiconductor device includes a meandering inductor and a shielding film with openings extending parallel to each other. The meandering inductor is configured by first and second inductors which are alternatively connected with each other. Also, there is provided a manufacturing method of the semiconductor device.

### BACKGROUND OF THE INVENTION

1. Field of the Invention

The present invention relates to a semiconductor device and a manufacturing method of the semiconductor device, in particular, to a semiconductor device which includes an inductor which is a high frequency passive element therein and a manufacturing method of the semiconductor device. This is a counterpart of and claims priority to Japanese Patent Application No. 2004-239305 filed on Aug. 19, 2004, which is herein incorporated by reference.

2. Description of the Related Art

Along with rapid diffusion of mobile communication devices represented by cellular phones in recent years, miniaturization and reduction of a thickness of a semiconductor device has been requested to be incorporated in the mobile communication devices. In general, high-frequency radio waves which have a microwave range as a center frequency are used for the mobile communication by the cellular phones or satellite communication. The semiconductor device which operates in the microwave range has a Monolithic Microwave Integrated Circuit (referred to as the “MMIC”) which includes an active element such as a transistor or a diode and a passive element such as a capacitor or an inductor disposed on a common semiconductor substrate together with each other. The combination between the MMIC and a high-density mounting technology such as a Chip Size Package (referred to as the “CSP”) makes contributions to realization of miniaturization and high effectiveness in the mobile communication devices. Hereupon, the inductor in the MMIC used for a coil of an impedance matching circuit generally includes a spiral inductor. Also, a shielding film is usually disposed between an electronic circuit formed in the semiconductor substrate and the spiral inductor in order to suppress electrical interference therebetween. The semiconductor device which has the spiral inductor is described in a Patent document 1 (Japanese Patent Publication Laid-open No. 2003-243570), in particular, on pages 8 through 9 and in FIGS. 11 and 12. The semiconductor device described in the Patent Document 1 has a mesh texture shielding film between the spiral inductor and the electronic circuit of the lower layer. Furthermore, the semiconductor device has another mesh texture shielding film between the spiral inductor and the antenna layer of the upper layer.

FIG. 1 is a schematic top view for describing a semiconductor device 1 which has a spiral inductor 7 in the related art. The semiconductor device 1 has a shielding film 5 between the spiral inductor 7 and an electronic circuit formed in a semiconductor substrate. The shielding film 5 has a plurality of openings 5A therein. The openings 5A are substantially square-shaped so that the shielding film 5 is mesh texture. In this example, twenty five of the openings 5A are formed in the shielding film 5. FIG. 2 is a schematic top view for describing a semiconductor device 10 which has a meandering inductor 17 in the another related art. The semiconductor device 10 has a shielding film 15 between the meandering inductor 17 and an electronic circuit formed in a semiconductor substrate. The shielding film 15 has a plurality of openings 15A therein. The openings 15A are substantially square-shaped so that the shielding film 15 is mesh texture. In this example, twenty five of the openings 15A are formed in the shielding film 15.

As described above, since the semiconductor device has the shielding film between the inductor which is the high-frequency passive element and the electronic circuit of the lower layer, electrical interference may be suppressed between the inductor and the electronic circuit. Therefore, the reliability of the semiconductor device may be improved. On the other hand, however, the inductance value of the inductor may be reduced because of electrical coupling between the inductor and the shielding film. In order to increase the inductance value of the inductor, the winding number of the inductor was increased in the related art. However, the increase of the winding number of the inductor induces increase of the area occupied by the inductor. As a result, the miniaturization of the semiconductor device may become hard to be realized. The above-described Patent Document 1 does not disclose the decrease of the inductance value caused by the electrical coupling between the spiral inductor and the shielding film. Also, the Document 1 does not disclose any countermeasures against the decrease of the inductance value of the inductor.

### SUMMARY OF THE INVENTION

An object of the present invention is to suppress electrical interference between the inductor and the electronic circuit, without decreasing the inductance value of the inductor.

According to an aspect of the present invention, for achieving the above-mentioned object, there is provided a semiconductor device which includes a semiconductor substrate having a principal surface in which a semiconductor integrated circuit is included. The semiconductor device further includes a spiral inductor which is disposed over the principal surface of the semiconductor substrate so as to be electrically coupled to the semiconductor integrated circuit. A region occupied by the spiral inductor is an inductor region. The semiconductor device still further includes a shielding film which is disposed between the principal surface of the semiconductor substrate and the spiral inductor. The shielding film includes a plurality of openings which radially extend in the shielding film from a middle of the inductor region toward a periphery of the inductor region.

According to another aspect of the present invention, for achieving the above-mentioned object, there is provided a semiconductor device which includes a semiconductor substrate having a principal surface in which a semiconductor integrated circuit is included. The semiconductor device further includes a meandering inductor which is disposed over the principal surface of the semiconductor substrate so as to be electrically coupled to the semiconductor integrated circuit. The meandering inductor includes a plurality of first inductors having first lengths and a plurality of second inductors having second lengths shorter than the first lengths. The first inductors and the second inductors are alternatively connected with each other. A region occupied by the meandering inductor is an inductor region. The semiconductor device still further includes a shielding film which is disposed between the principal surface of the semiconductor substrate and the meandering inductor. The shielding film includes a plurality of openings which respectively extend from a first side of the inductor region toward an opposite second side of the inductor region and across the first inductors of the meandering inductor.

According to another aspect of the present invention, for achieving the above-mentioned object, there is provided a manufacturing method of a semiconductor device. In the manufacturing method, a semiconductor substrate including a principal surface is provided. Then, a semiconductor integrated circuit is formed in the principal surface of the semiconductor substrate. A region occupied by the semiconductor integrated circuit is an element region. Next, a shielding film is formed over the element region of the principal surface of the semiconductor substrate so that the shielding film includes a plurality of openings. The openings extend from a middle of the element region toward a periphery of the element region. Thereafter, a spiral inductor is formed on the shielding film formed over the element region, so that the spiral inductor extends across and over the openings of the shielding film and are electrically coupled to the semiconductor integrated circuit.

According to another aspect of the present invention, for achieving the above-mentioned object, there is provided a manufacturing method of a semiconductor device. In the manufacturing method, a semiconductor substrate including a principal surface is provided. Then, a semiconductor integrated circuit is formed in the principal surface of the semiconductor substrate. A region occupied by the semiconductor integrated circuit is an element region. Next, a shielding film is formed over the element region of the principal surface of the semiconductor substrate so that the shielding film includes a plurality of openings. The openings respectively extend from a first side of the element region toward an opposite second side of the element region. Thereafter, a meandering inductor is formed on the shielding film formed over the element region so that the meandering inductor is electrically coupled to the semiconductor integrated circuit. The meandering inductor includes a plurality of first inductors having first lengths and a plurality of second inductors having second lengths shorter than the first lengths. The first inductors and the second inductors are alternatively connected with each other. The first inductors of the meandering inductor extend across and over the openings of the shielding film.

The above and further aspects and novel features of the invention will more fully appear from the following detailed description, appended claims and the accompanying drawings.

### BRIEF DESCRIPTION OF THE DRAWINGS

FIG. 1 is a schematic top view for describing a semiconductor device which has a spiral inductor in the related art.

FIG. 2 is a schematic top view for describing a semiconductor device which has a meandering inductor in the another related art.

FIG. 3A is a schematic top view for describing a semiconductor device which has a spiral inductor according to a first preferred embodiment of the present invention.

FIG. 3B is a schematic sectional view along a dashed line A-A′ of the semiconductor device in FIG. 3A.

FIG. 4A is a graph showing a comparison result by a finite element simulation with respect to the inductance value of the spiral inductor between the semiconductor device in the related art in FIG. 1 and the semiconductor device according to the first preferred embodiment in FIGS. 3A and 3B.

FIG. 4B is a graph showing a comparison result by a finite element simulation with respect to the inductance values of the spiral inductors depending on the number of the openings between the semiconductor device in the related art in FIG. 1 and the semiconductor device according to the first preferred embodiment in FIGS. 3A and 3B.

FIG. 5A is a schematic top view for describing a semiconductor device which has a spiral inductor according to a second preferred embodiment of the present invention.

FIG. 5B is a schematic sectional view along a dashed line B-B′ of the semiconductor device in FIG. 5A.

FIG. 6A is a schematic top view for describing a semiconductor device which has a meandering inductor according to a third preferred embodiment of the present invention.

FIG. 6B is a schematic sectional view along a dashed line C-C′ of the semiconductor device in FIG. 6A.

FIG. 7A is a schematic top view for describing a semiconductor device which has a meandering inductor according to a fourth preferred embodiment of the present invention.

FIG. 7B is a schematic sectional view along a dashed line D-D′ of the semiconductor device in FIG. 7A.

### DETAILED DESCRIPTION OF THE PREFERRED EMBODIMENTS

Embodiments of the present invention will be described hereinafter with references to the accompanying drawings. The drawings used for this description illustrate major characteristic parts of embodiments in order that the present invention will be easily understood. However, the invention is not limited by these drawings.

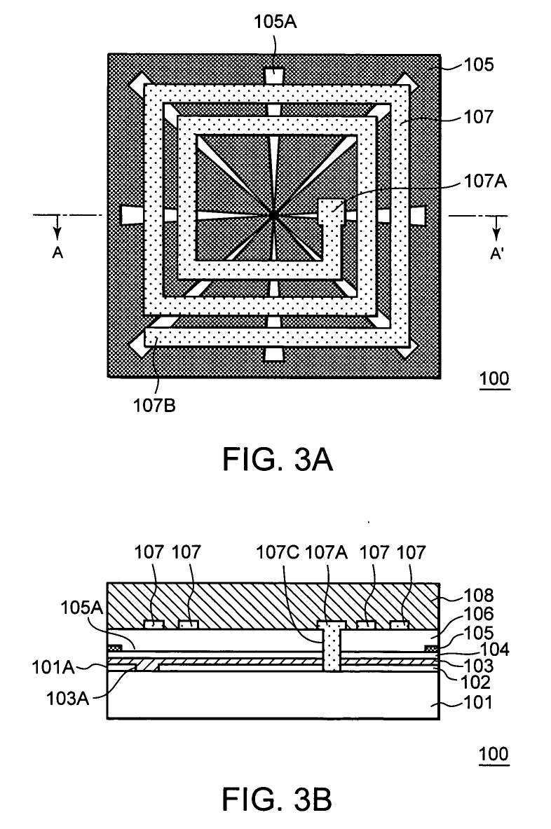

FIG. 3A is a schematic top view for describing a semiconductor device 100 which has a spiral inductor 107 according to a first preferred embodiment of the present invention. FIG. 3B is a schematic sectional view along a dashed line A-A′ of the semiconductor device 100 in FIG. 3A.

The semiconductor device 100 has a semiconductor integrated circuit which operates in the microwave range. As shown in FIG. 3B, the semiconductor integrated circuit is formed in a principal surface 101A of a semiconductor substrate 101. The semiconductor integrated circuit may include a plurality of semiconductor elements such as transistors. The semiconductor device 100 has an insulating film 102 disposed on the semiconductor substrate 101 so as to cover the principal surface 101A. In this example, the insulating film 102 may be a silicon dioxide film, for example. A plurality of interconnection films 103 are disposed on the insulating film 102 so that each of the interconnection films 103 is coupled to the semiconductor integrated circuit through a contact portion 103A of the interconnection film 103. The contact portion 103A is disposed in the insulating film 102 as shown in FIG. 3B. The interconnection films 103 may include aluminum, or the like. A first protective film 104 is a passivation film disposed on the insulating film 102 so as to cover the interconnection films 103. The first protective film 104 protects the semiconductor substrate 101 from mechanical stresses or ingression of impurities. In this example, the first protective film 104 may be a silicon dioxide film or a silicon nitride film.

The semiconductor device 100 also has a shielding film 105 disposed on the first protective film 104. The shielding film 105 has a plurality of openings 105A which radially extend from a middle of the shielding film 105 toward a periphery of the shielding film 105 as shown in FIG. 3A. The shielding film 105 may include aluminum. In addition, the shielding film 105 may include copper. The numberof the openings 105 may be more than four. In this example, the openings 105A are triangular and formed entirely through the shielding film 105. That is, each width of the openings 105A gets wider from the middle of the shielding film 105 toward the periphery of the shielding film 105. Alternatively, the openings 105A may have rectangular shapes which extend from the middle of the shielding film 105 toward the periphery of the shielding film 105. In addition, the shielding film 105 is coupled to a ground voltage. A second protective film 106 is disposed on the shielding film 105 so that the openings 105A are filled with the second protective film 106 and so that the shielding film 105 is covered by the second film 106. The second protective film 106 is a polyimide film. A thickness of the second protective film 106 ranges approximately from 5 to 10 μm.

Furthermore, the semiconductor device 100 has the spiral inductor 107 disposed on the second protective film 106. The spiral inductor 107 may include copper. The spiral inductor 107 has one end portion 107A which is electrically coupled to the semiconductor integrated circuit through a contact portion 107C of the spiral inductor 107 as shown in FIG. 3B. The spiral inductor 107 also has another end portion 107B which is electrically coupled to after-described external electrode. It is assumed that a region occupied by the spiral inductor 107 is an inductor region, the openings 105A of the shielding film 105 radially extend in the shielding film 105 from a middle of the inductor region toward a periphery of the inductor region. The shielding film 105 which has the openings 105A suppresses electrical interference between the semiconductor integrated circuit and the spiral inductor 107 without decreasing the inductance value of the spiral inductor 107. The semiconductor device 100 has a sealing resin film 108 disposed on the second protective film 106. The sealing resin film 108 covers the spiral inductor 107. The sealing resin film 108 may be a heat-hardening resin such as an epoxy resin. The semiconductor device 100 also has a plurality of the external electrodes disposed on the sealing resin film 108. The external electrodes are electrically coupled to the other end portion 107B of the spiral inductor 107 and the semiconductor integrated circuit through the interconnection films 103.

The manufacturing method of the semiconductor device 100 is described below.

After a semiconductor substrate such as a semiconductor wafer is provided, a plurality of semiconductor integrated circuits are formed in a principal surface of the semiconductor substrate. Each of regions occupied by the semiconductor integrated circuits is an element region. Then, the silicon dioxide film as the insulating film 102 is formed on the principal surface of the semiconductor wafer by a Chemical Vapor Deposition (CVD) method, so as to cover each of the element regions. Next, the interconnection films 103 are formed on the insulating film by a sputtering method and photolithography and etching methods, so as to be coupled to the semiconductor integrated circuits through the contact portions 103A. The first protective film 104 is formed so as to cover the interconnection films 103 and the remaining exposed portions of the insulating film 102 by the CVD method. The shielding layer 105 is formed on the first protective film 104 by the sputtering method. The openings 105A are formed by patterning the shielding film 105 by the photolithography and etching methods, so as to extend from a middle of the element region toward a periphery of the element region. The manufacturing processes from forming the semiconductor integrated circuits till forming the openings 105A are executed in a front-end wafer process.

Thereafter, the second protective film 106 is formed on the shielding film 105 so that the openings 105A are filled with the second protective film 106. Next, a copper film is deposited on the second protective film 106 by the sputtering method, so as to be coupled to the semiconductor integrated circuits through the contact portion 107C. Then, the copper film is patterned by the photolithography and etching methods in order to form a plurality of the spiral inductors 107. Each of the spiral inductors 107 corresponds to each of the semiconductor integrated circuits. Furthermore, the sealing resin film 108 is formed on the second protective film 106 so as to cover the spiral inductor 107, and the external electrodes are formed on the sealing resin film 108. After forming the external electrodes, the semiconductor wafer is divided into a plurality of semiconductor devices 100 which respectively have the spiral inductors 107 formed on the semiconductor substrate 101. The manufacturing processes from forming the second protective film 106 till dividing the semiconductor wafer are executed in a post-process.

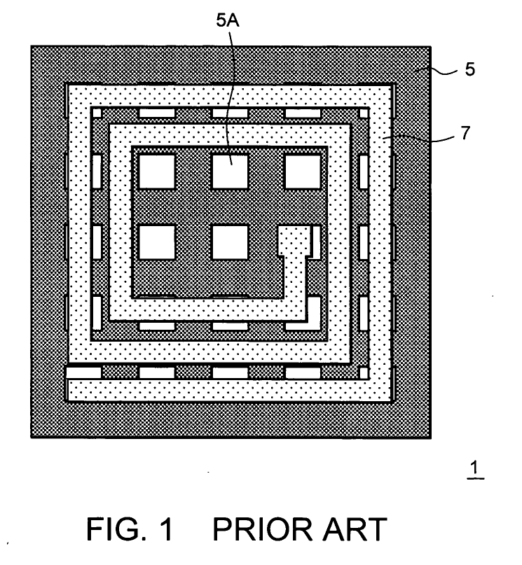

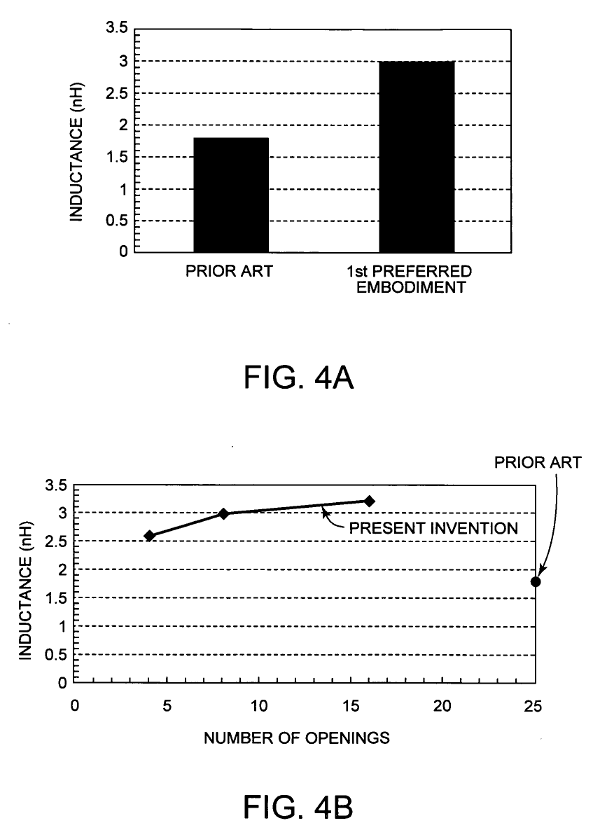

FIG. 4A is a graph showing a comparison result by a finite element simulation with respect to the inductance values of the spiral inductors between the semiconductor device 1 in the related art in FIG. 1 and the semiconductor device 100 according to the first preferred embodiment in FIGS. 3A and 3B. In the finite element simulation, an area of the shielding film 5 excluding the twenty five openings 5A in the semiconductor device 1 is set to be equal to an area of the shielding film 105 excluding the eight openings 105A in the semiconductor device 100. Also, although not shown in the Figs, each of the spiral inductors 7 and 107 have 4.5 turns and an operating frequency of 0.9 GHz. As is clear from FIG. 4A, compared with approximately 1.8 nH of the inductance value of the spiral inductor 7, which is shown by a dashed line, in the semiconductor device 1 according to the related art in FIG. 1, the inductance value of the spiral inductor 107 in the semiconductor device 100 according to the first preferred embodiment in FIGS. 3A and 3B is 3.0 nH. That is, the inductance value of the spiral inductor 107 is approximately 1.67 times the inductance value of the spiral inductor 7.

FIG. 4B is a graph showing a comparison result by a finite element simulation with respect to the inductance values of the spiral inductors depending on the number of the openings in the shielding film between the semiconductor device 1 in the related art in FIG. 1, and the semiconductor device 100 according to the first preferred embodiment in FIGS. 3A and 3B. The simulation has been respectively executed when the number of the openings 105A in the shielding films 105 of the semiconductor device 100 according to the first preferred embodiment is 4, 8 or 16. Also, each of the areas of the shielding films 105 excluding the four openings 105A, the eight openings 105A or the sixteen openings 105A is set to be equal to the area of the shielding film 5 excluding the twenty five openings 5A in the semiconductor device 1. Furthermore, although not shown in the Figs, each of the spiral inductors 7 and 107 have 4.5 turns and an operating frequency of 0.9 GHz. As is clear from FIG. 4B, compared with approximately 1.8 nH of the inductance value of the spiral inductor 7 in the semiconductor device 1 according to the related art in FIG. 1, each of the semiconductor devices 100, which has the four openings 105A, the eight openings 105A or the sixteen openings 105A, has a greater inductance value of the spiral inductor 107. That is, as described above, the number of the openings 105A may be more than four in the first preferred embodiment of the present invention.

According to the first preferred embodiment, the shielding film has a plurality of the openings which radially extend from the middle of the inductor region, in which the spiral inductor is arranged, toward the periphery of the inductor region. Therefore, electrical interference may be suppressed from arising between the semiconductor integrated circuit and the spiral inductor, while the inductance value of the spiral inductor is suppressed from decreasing. That is, it is not necessary to increase the area occupied by the spiral inductor in order to keep desired inductance value of the spiral inductor, when the semiconductor device has the shielding layer between the semiconductor integrated circuit and the spiral inductor. As a result, electrical interference may be suppressed from arising between the semiconductor integrated circuit and the spiral inductor while the semiconductor device may be miniaturized.

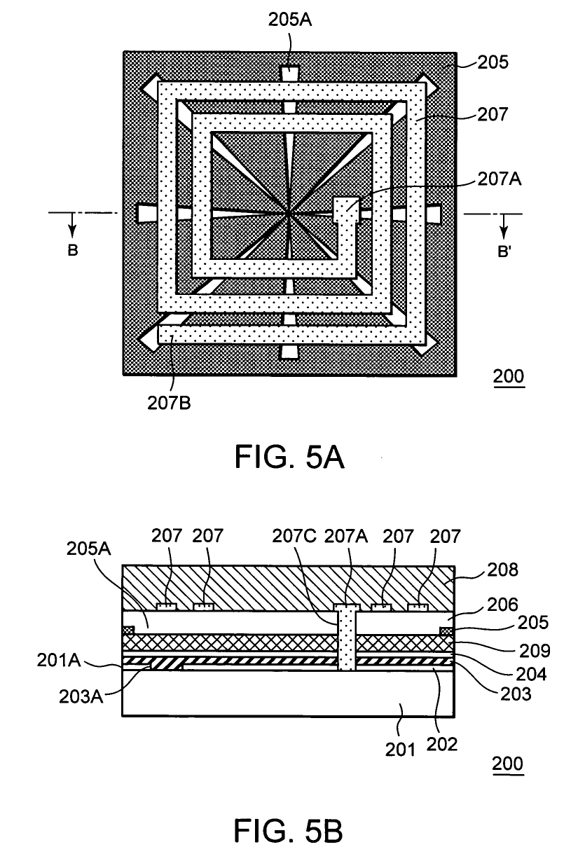

FIG. 5A is a schematic top view for describing a semiconductor device 200 which has a spiral inductor 207 according to a second preferred embodiment of the present invention. FIG. 5B is a schematic sectional view along a dashed line B-B′ of the semiconductor device 200 in FIG. 5A. The semiconductor device 200 according to the second preferred embodiment has a third protective film 209 in addition to first and second protective films 204 and 206.

The semiconductor device 200 has a semiconductor integrated circuit which operates in the microwave range. As shown in FIG. 5B, the semiconductor integrated circuit is formed in a principal surface 201A of a semiconductor substrate 201. The semiconductor integrated circuit may include a plurality of semiconductor elements such as transistors. The semiconductor device 200 has an insulating film 202 and a plurality of interconnection films 203 sequentially disposed on the principal surface 201A of the semiconductor substrate 201. In this example, the insulating film 202 may be a silicon dioxide film, and the interconnection films 203 may include aluminum. The interconnection film 203 is coupled to the semiconductor integrated circuit through a contact portion 203A of the interconnection film 203. The contact portion 203A is disposed in the insulating film 202 as shown in FIG. 5B. The interconnection films 203 are covered with a first protective film 204. The first protective film 204 is a passivation film disposed on the insulating film 202 and the interconnection films 203. The first protective film 204 protects the semiconductor substrate 201 from the mechanical stresses or the ingression of the impurities. In this example, the first protective film 204 may be a silicon dioxide film or a silicon nitride film.

As described above, the semiconductor device 200 has the third protective film 209 disposed on the first protective film 204. The third protective film 209 may be a polyimide resin. The semiconductor device 200 also has the shielding film 205 as well as the semiconductor device 100. The shielding film 205 which may include copper is disposed on the third protective film 209. In addition, the shielding film 205 may include aluminum. The shielding film 205 has a plurality of openings 205A which radially extend from a middle of the shielding film 205 toward a periphery of the shielding film 205 as shown in FIG. 5A. The number of the openings 205A may be more than four. In this example, the openings 205A are triangular and formed entirely through the shielding film 205. That is, each width of the openings 205A gets wider from the middle of the shielding film 205 toward the periphery of the shielding film 205. Alternatively, the openings 205A may have rectangular shapes which extend from the middle of the shielding film 205 toward the periphery of the shielding film 205. In addition, the shielding film 205 is coupled to the ground voltage.

Furthermore, the semiconductor device 200 has the spiral inductor 207 disposed on the shielding film 205 through a second protective film 206. The second protective film 206 is disposed on the shielding film 205 so that the openings 205A are filled with the second protective film 206 and so that the shielding film 205 is covered by the second film 206. The second protective film 206 is a polyimide film and has a thickness which ranges approximately from 5 to 10 μm. The spiral inductor 207 may include copper. The spiral inductor 207 has one end portion 207A which is electrically coupled to the semiconductor integrated circuit through a contact portion 207C of the spiral inductor 207 as shown in FIG. 5B. The spiral inductor 207 also has another end portion 207B which is electrically coupled to after-described external electrode. It is assumed that a region occupied by the spiral inductor 207 is an inductor region, the openings 205A of the shielding film 205 radially extend in the shielding film 205 from a middle of the inductor region toward a periphery of the inductor region. The shielding film 205 which has the openings 205A suppresses electrical interference between the semiconductor integrated circuit and the spiral inductor 207, without decreasing the inductance value of the spiral inductor 207. The semiconductor device 200 has a sealing resin film 208 disposed on the second protective film 206. The sealing resin film 208 covers the spiral inductor 207. The sealing resin film 208 includes heat-hardening resin such as epoxy resin. The semiconductor device 200 also has a plurality of the external electrodes disposed on the sealing resin film 208. The external electrodes are electrically coupled to the other end portion 207B of the spiral inductor 207 and the semiconductor integrated circuit through the interconnection films 203.

Also in the second preferred embodiment, the inductance value of the spiral inductor 207 in the semiconductor device 200 is approximately 1.67 times the inductance value of the spiral inductor 7 in the semiconductor device 1 in FIG. 1, in a manner similar as in the first preferred embodiment. Furthermore, when the shielding film 205 has more than four openings 205A, the inductance value of the spiral inductor 207 in the semiconductor device 200 is greater than that of the spiral inductor 7 in the semiconductor device 1 according to the related art, in a manner as in the first preferred embodiment.

The manufacturing method of the semiconductor device 200 is described below.

After a semiconductor substrate such as a semiconductor wafer is provided, a plurality of semiconductor integrated circuits are formed in a principal surface of the semiconductor substrate. Each of regions occupied by the semiconductor integrated circuits is an element region. Then, the silicon dioxide film as the insulating film 202 is formed on the principal surface of the semiconductor wafer by the CVD method, so as to cover each of the element regions. Next, the interconnection films 203 are formed by the sputtering method and photolithography and etching methods, so as to be coupled to the semiconductor integrated circuits through the contact portions 203A. The first protective film 204 is formed so as to cover the interconnection films 203 and the insulating film 202 by the CVD method. The manufacturing processes from forming the semiconductor integrated circuits till forming the first protective film 204 are executed in the front-end wafer process.

Thereafter, the third protective film 209 which includes the polyimide resin is formed on the first protective film 204. Then, the shielding layer 205 is formed on the third protective film 209 by the sputtering method so as to be electrically coupled to one of the interconnection films 203 which receives the ground voltage. The openings 205A are formed by patterning the shielding film 205 by the photolithography and etching methods, so as to extend from a middle of the element region toward a periphery of the element region. The second protective film 206 is formed on the shielding film 205 so that the openings 205A are filled with the second protective film 206. Next, a copper film is deposited on the second protective film 206 by the sputtering method, so as to be coupled to the semiconductor integrated circuits through the contact portion 207C. Then, the copper film is patterned by the photolithography and etching methods in order to form a plurality of the spiral inductors 207. Each of the spiral inductors 207 corresponds to respective ones of the semiconductor integrated circuits. Furthermore, the sealing resin film 208 is formed on the second protective film 206 so as to cover the spiral inductor 207, and the external electrodes are formed on the sealing resin film 208. After forming the external electrodes, the semiconductor wafer is divided into a plurality of semiconductor devices 200 which respectively have the spiral inductors 207 formed on the semiconductor substrate 201. The manufacturing processes from forming the third protective film 209 till dividing the semiconductor wafer are executed in the post-process.

According to the second preferred embodiment, the shielding film has a plurality of the openings which radially extend from the middle of the inductor region, in which the spiral inductor is arranged, toward the periphery of the inductor region. Therefore, electrical interference may be suppressed from arising between the semiconductor integrated circuit and the spiral inductor, while the inductance value of the spiral inductor is suppressed from decreasing. That is, it is not necessary to increase the area occupied by the spiral inductor in order to keep desired inductance value of the spiral inductor, when the semiconductor device has the shielding layer between the semiconductor integrated circuit and the spiral inductor. As a result, electrical interference may be suppressed from arising between the semiconductor integrated circuit and the spiral inductor while the semiconductor device may be miniaturized. Furthermore, since the third protective film is formed on the first protective film before the shielding film is formed, the shielding film and the spiral inductor may be formed in the post process.

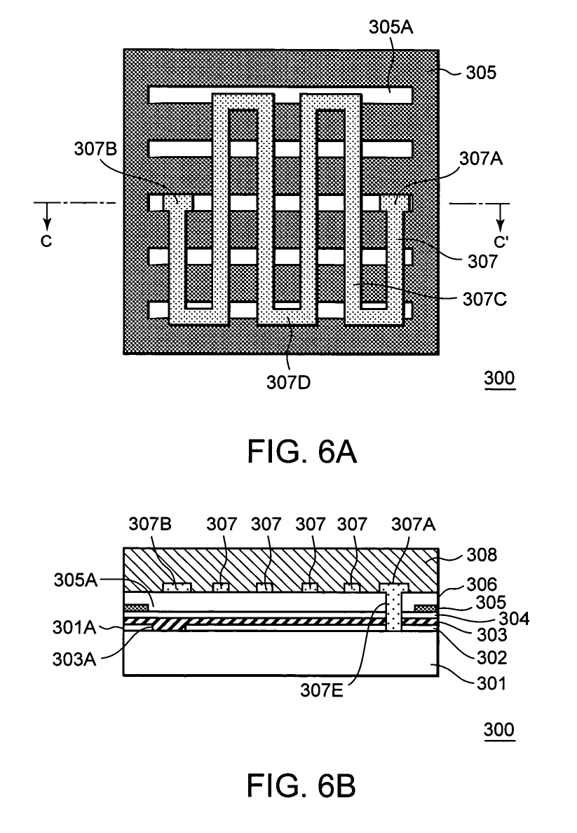

FIG. 6A is a schematic top view for describing a semiconductor device 300 which has a meandering inductor 307 according to a third preferred embodiment of the present invention. FIG. 6B is a schematic sectional view along a dashed line C-C′ of the semiconductor device 300 in FIG. 6A.

The semiconductor device 300 has a semiconductor integrated circuit which operates in the microwave range. As shown in FIG. 6B, the semiconductor integrated circuit is formed in a principal surface 301A of a semiconductor substrate 301. The semiconductor integrated circuit may include a plurality of semiconductor elements such as transistors. The semiconductor device 300 has an insulating film 302 disposed on the semiconductor substrate 301 so as to cover the principal surface 301A. In this example, the insulating film 302 may be a silicon dioxide film. A plurality of interconnection films 303 are disposed on the insulating film 302 so that each of the interconnection films 303 is coupled to the semiconductor integrated circuit through a contact portion 303A of the interconnection film 303. The contact portion 303A is disposed in the insulating film 302 as shown in FIG. 6B. The interconnection films 303 may include aluminum. A first protective film 304 is a passivation film disposed on the insulating film 302 so as to cover the interconnection films 303. The first protective film 304 protects the semiconductor substrate 301 from the mechanical stresses or the ingression of the impurities. In this example, the first protective film 304 may be a silicon dioxide film or a silicon nitride film.

The semiconductor device 300 also has a shielding film 305 disposed on the first protective film 304. The shielding film 305 may include aluminum. In addition, the shielding film 105 may include copper. The shielding film 305 has a plurality of openings 305A which respectively extend from one side of the shielding film 305 toward the other opposite side of the shielding film 305 as shown in FIG. 6A. In this example, the openings 305A are formed entirely through the shielding film 305 and the number of the openings 305A is five. The openings 305A are arranged in parallel with each other. In addition, the shielding film 305 is coupled to the ground voltage. A second protective film 306 is disposed on the shielding film 305 so that the openings 305A are filled with the second protective film 306 and so that the shielding film 305 is covered by the second film 306. The second protective film 306 is a polyimide film. A thickness of the second protective film 306 ranges approximately from 5 to 10 μm.

Furthermore, the semiconductor device 300 has the meandering inductor 307 disposed on the second protective film 306. The meandering inductor 307 may include copper. The meandering inductor 307 has a plurality of first inductors 307C and a plurality of second inductors 307D. Each of the first inductors 307C has a first length, and each of the second inductors 307D has a second length which is shorter than the first length. The first inductors 307C and the second inductors 307D are alternatively connected with each other. The first inductors 307C respectively extend substantially perpendicularly across the openings 305A of the shielding film 305. The meandering inductor 307 has one end portion 307A which is electrically coupled to the semiconductor integrated circuit through a contact portion 307E of the meandering inductor 307 as shown in FIG. 6B. The meandering inductor 307 also has another end portion 307B which is electrically coupled to after-described external electrode. It is assumed that a region occupied by the meandering inductor 307 is an inductor region, the openings 305A of the shielding film 305 respectively extend in the shielding film 305 from a first side of the inductor region toward an opposite second side of the inductor region. The shielding film 305 which has the openings 305A suppresses the electrical interference between the semiconductor integrated circuit and the meandering inductor 307, without decreasing the inductance value of the meandering inductor 307. The semiconductor device 300 has a sealing resin film 308 disposed on the second protective film 306. The sealing resin film 308 covers the meandering inductor 307. The sealing resin film 308 may include a heat-hardening resin such as an epoxy resin. The semiconductor device 300 also has a plurality of the external electrodes disposed on the sealing resin film 308. The external electrodes are electrically coupled to the other end portion 307B of the meandering inductor 307 and the semiconductor integrated circuit through the interconnection films 303.

The manufacturing method of the semiconductor device 300 is described below.

After a semiconductor substrate such as a semiconductor wafer is provided, a plurality of semiconductor integrated circuits are formed in a principal surface of the semiconductor substrate. Each of regions occupied by the semiconductor integrated circuits is an element region. Then, the silicon dioxide film as the insulating film 302 is formed on the principal surface of the semiconductor substrate by the CVD method, so as to cover each of the element regions. Next, the interconnection films 303 are formed by the sputtering method and the photolithography and etching methods, so as to be coupled to the semiconductor integrated circuits through the contact portions 303A. The first protective film 304 is formed so as to cover the interconnection films 303 and the insulating film 302 by the CVD method. The shielding layer 305 is formed on the first protective film 304 by the sputtering method. The openings 305A are formed by patterning the shielding film 305 by the photolithography and etching methods, so as to extend from a first side of the element region toward an opposite second side of the element region. The manufacturing processes from forming the semiconductor integrated circuits till forming the openings 305A are executed in the front-end wafer process.

Thereafter, the second protective film 306 is formed on the shielding film 305 so that the openings 305A are filled with the second protective film 306. Next, a copper film is deposited on the second protective film 306 by the sputtering method, so as to be coupled to the semiconductor integrated circuits through the contact portion 307E. Then, the copper film is patterned by the photolithography and etching methods in order to form a plurality of the meandering inductors 307. Each of the meandering inductors 307 corresponds to respective ones of the semiconductor integrated circuits. Furthermore, the sealing resin film 308 is formed on the second protective film 306 so as to cover the meandering inductor 307, and the external electrodes are formed on the sealing resin film 308. After forming the external electrodes, the semiconductor wafer is divided into a plurality of semiconductor devices 300 which respectively have the meandering inductors 307 formed on the semiconductor substrate 301. The manufacturing processes from froming the second protective film 306 till dividing the semiconductor wafer are executed in the post-process.

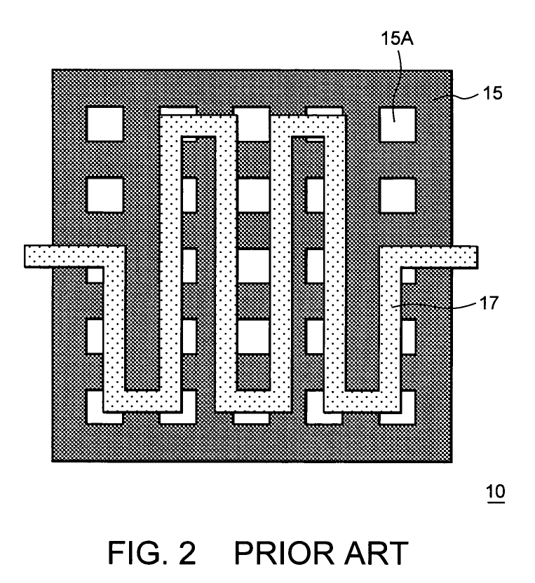

A comparison result is described below, by the finite element simulation with respect to the inductance values of the meandering inductors between the semiconductor device 10 in the related art in FIG. 2 and the semiconductor device 300 according to the third preferred embodiment in FIGS. 6A and 6B. In the finite element simulation, an area of the shielding film 15 excluding the twenty five openings 15A in the semiconductor device 10 is set to be equal to an area of the shielding film 305 excluding the five openings 305A in the semiconductor device 300. Also, the operating frequency of the meandering inductors 17 and 307 are 0.9 GHz. The simulation has found that the inductance value of the meandering inductor 307 in the semiconductor device 300 according to the third preferred embodiment in FIGS. 6A and 6B is 1.4 nH, compared with approximately 1.3 nH of the inductance value of the meandering inductor 17 in the semiconductor device 10 according to the related art in FIG. 2. That is, the inductance value of the meandering inductor 307 is approximately 1.08 times the inductance value of the meandering inductor 17.

According to the third preferred embodiment, the shielding film has a plurality of the openings which respectively extend from the one side of the inductor region, in which the meandering inductor is arranged, toward the opposite side of the inductor region. Therefore, electrical interference may be suppressed from arising between the semiconductor integrated circuit and the meandering inductor, while the inductance value of the meandering inductor is suppressed from decreasing. That is, it is not necessary to increase the area occupied by the meandering inductor in order to keep desired inductance value of the meandering inductor, when the semiconductor device has the shielding layer between the semiconductor integrated circuit and the meandering inductor. As a result, the electrical interference may be suppressed from arising between the semiconductor integrated circuit and the meandering inductor while the semiconductor device may be miniaturized.

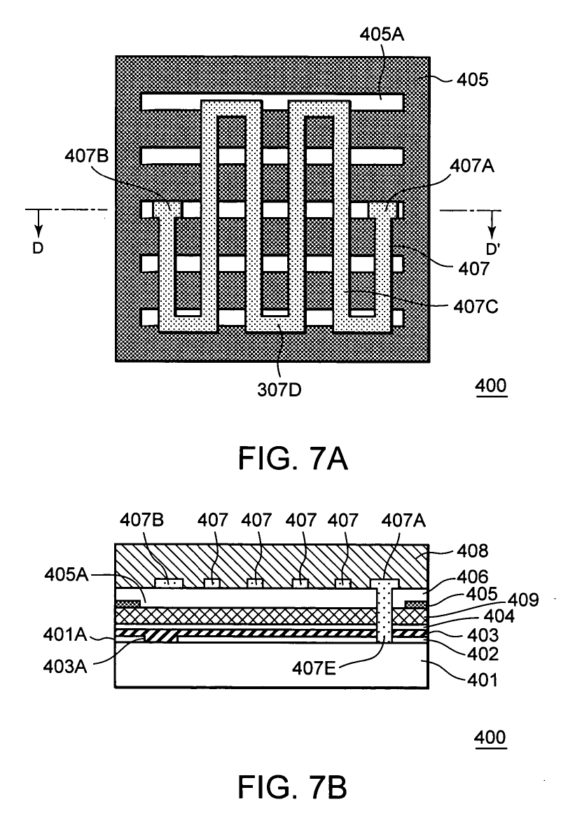

FIG. 7A is a schematic top view for describing a semiconductor device 400 which has a meandering inductor 407 according to a fourth preferred embodiment of the present invention. FIG. 7B is a schematic sectional view along a dashed line D-D′ of the semiconductor device 400 in FIG. 7A. The semiconductor device 400 according to the fourth preferred embodiment has a third protective film 409 in addition to first and second protective films 404 and 406.

The semiconductor device 400 has a semiconductor integrated circuit which operates in the microwave range. As shown in FIG. 7B, the semiconductor integrated circuit is formed in a principal surface 401A of a semiconductor substrate 401. The semiconductor integrated circuit may include a plurality of semiconductor elements such as transistors. The semiconductor device 400 has an insulating film 402 disposed on the semiconductor substrate 401 so as to cover the principal surface 401A. In this example, the insulating film 402 may be a silicon dioxide film. A plurality of interconnection films 403 are disposed on the insulating film 402 so that each of the interconnection films 403 is coupled to a semiconductor integrated circuit through a contact portion 403A of the interconnection film 403. The contact portion 403A is disposed in the insulating film 402 as shown in FIG. 7B. The interconnection films 403 may include aluminum. The first protective film 404 is a passivation film disposed on the insulating film 402 so as to cover the interconnection films 403. The first protective film 404 protects the semiconductor substrate 401 from the mechanical stresses or the ingression of the impurities. In this example, the first protective film 404 may be a silicon dioxide film or a silicon nitride film.

As described above, the semiconductor device 400 has the third protective film 409 disposed on the first protective film 404. The third protective film 409 includes a polyimide resin. The semiconductor device 400 also has a shielding film 405 disposed on the first protective film 404. The shielding film 405 may include aluminum. In addition, the shielding film 405 may include copper. The shielding film 405 has a plurality of openings 405A which respectively extend from one side of the shielding film 405 toward the other opposite side of the shielding film 405 as shown in FIG. 7A. In this example, the openings 405A are formed entirely through the shielding film 405 and the number of the openings 405A is five. The openings 405A are arranged in parallel with each other. In addition, the shielding film 405 is coupled to the ground voltage.

Furthermore, the semiconductor device 400 has the meandering inductor 407 disposed on the shielding film 405 through the second protective film 406. The second protective film 406 is disposed on the shielding film 405 so that the openings 405A are filled with the second protective film 406 and so that the shielding film 405 is covered by the second film 406. The second protective film 406 is a polyimide film and has a thickness which ranges approximately from 5 to 10 μm. The meandering inductor 407 may include copper. The meandering inductor 407 has a plurality of first inductors 407C and a plurality of second inductors 407D. Each of the first inductors 407C has a first length, and each of the second inductors 407D has a second length which is shorter than the first length. The first inductors 407C and the second inductors 407D are alternatively connected with each other. The first inductors 407C respectively extend substantially perpendicularly across the openings 405A of the shielding film 405. The meandering inductor 407 has one end portion 407A which is electrically coupled to the semiconductor integrated circuit through a contact portion 407E of the spiral inductor 407 as shown in FIG. 7B. The meandering inductor 407 also has another end portion 407B which is electrically coupled to after-described external electrode. It is assumed that a region occupied by the meandering inductor 407 is an inductor region, the openings 405A of the shielding film 405 respectively extend in the shielding film 405 from a first side of the inductor region toward an opposite second side of the inductor region. The shielding film 405 which has the openings 405A suppresses electrical interference between the semiconductor integrated circuit and the meandering inductor 407, without decreasing the inductance value of the meandering inductor 407. The semiconductor device 400 has a sealing resin film 408 disposed on the second protective film 406. The sealing resin film 408 covers the meandering inductor 407. The sealing resin film 408 may include a heat-hardening resin such as an epoxy resin. The semiconductor device 400 also has a plurality of the external electrodes disposed on the sealing resin film 408. The external electrodes are electrically coupled to the other end portion 407B of the meandering inductor 407 and the semiconductor integrated circuit through the interconnection films 403.

Also in the fourth preferred embodiment, the inductance value of the meandering inductor 407 in the semiconductor device 400 is approximately 1.08 times the inductance value of the meandering inductor 17 in the semiconductor device 10 in FIG. 2.

The manufacturing method of the semiconductor device 400 is described below.

After a semiconductor substrate such as a semiconductor wafer is provided, a plurality of semiconductor integrated circuits are formed in a principal surface of the semiconductor substrate. Each of regions occupied by the semiconductor integrated circuits is an element region. Then, the silicon dioxide film as the insulating film 402 is formed on the principal surface of the semiconductor substrate by the CVD method, so as to cover each of the element regions. Next, the interconnection films 403 are formed by the sputtering method and the photolithography and etching methods. The first protective film 404 is formed so as to cover the interconnection films 403 by the CVD method. The manufacturing processes from forming the semiconductor integrated circuits till forming the first protective film 404 are executed in the front-end wafer process.

Thereafter, the third protective film 409 which includes the polyimide resin is formed on the first protective film 404. Then, the shielding layer 405 is formed on the first protective film 404 by the sputtering method so as to be electrically coupled to one of the interconnection films 403 which receives the ground voltage. The openings 405A are formed by patterning the shielding film 405 by the photolithography and etching methods, so as to extend from a first side of the element region toward a second opposite side of the element region. The second protective film 406 is formed on the shielding film 405 so that the openings 405A are filled with the second protective film 406. Next, a copper film is deposited on the second protective film 406 by the sputtering method, so as to be coupled to the semiconductor integrated circuits through the contact portion 407E. Then, the copper film is patterned by the photolithography and etching methods in order to form a plurality of the meandering inductors 407. Each of the meandering inductors 407 corresponds to respective ones of the semiconductor integrated circuits. Furthermore, the sealing resin film 408 is formed on the second protective film 406 so as to cover the meandering inductor 407, and the external electrodes are formed on the sealing resin film 408. After forming the external electrodes, the semiconductor substrate is divided into a plurality of semiconductor devices 400 which respectively have the meandering inductors 407 formed on the semiconductor substrate 401. The manufacturing processes from forming the third protective film 409 till dividing the semiconductor substrate are executed in the post-process.

According to the fourth preferred embodiment, the shielding film has a plurality of the openings which respectively extend from the one side of the inductor region, in which the meandering inductor is arranged, toward the opposed side of the inductor region. Therefore, electrical interference may be suppressed from arising between the semiconductor integrated circuit and the meandering inductor, while the inductance value of the meandering inductor is suppressed from decreasing. That is, it is not necessary to increase the area occupied by the meandering inductor in order to keep desired inductance value of the meandering inductor, when the semiconductor device has the shielding layer between the semiconductor integrated circuit and the spiral inductor. As a result, electrical interference may be suppressed from arising between the semiconductor integrated circuit and the meandering inductor while the semiconductor device may be miniaturized. Furthermore, since the third protective film is formed on the first protective film before the shielding film is formed, the shielding film and the meandering inductor may be formed in the post process.

What is claimed is:

1. A semiconductor device, comprising:
a semiconductor substrate having a principal surface in which a semiconductor integrated circuit is included;
a spiral inductor disposed over the principal surface of the semiconductor substrate so as to be electrically coupled to the semiconductor integrated circuit, wherein a region occupied by the spiral inductor is an inductor region; and
a shielding film disposed between the principal surface of the semiconductor substrate and the spiral inductor, the shielding film including a plurality of openings therein entirely through the shielding film, wherein the openings radially extend in the shielding film from a middle of the inductor region toward a periphery of the inductor region.

2. The semiconductor device according to claim 1, wherein the shielding film includes one of aluminum and copper.

3. The semiconductor device according to claim 1, wherein the shielding film has at least four of the openings.

4. The semiconductor device according to claim 1, wherein widths of the openings become wider with increasing distance from the middle of the inductor region toward the periphery of the inductor region.

5. The semiconductor device according to claim 1, further comprising:
a plurality of interconnection films disposed over the principal surface of the semiconductor substrate, wherein the interconnection films are coupled to the semiconductor integrated circuit; and
a polyimide film disposed over the principal surface of the semiconductor substrate so as to cover the interconnection films.

6. The semiconductor device according to claim 1, wherein the shielding film is coupled to a ground voltage.

7. A semiconductor device, comprising:
a semiconductor substrate having a principal surface in which a semiconductor integrated circuit is included;
a meandering inductor disposed over the principal surface of the semiconductor substrate so as to be electrically coupled to the semiconductor integrated circuit, wherein the meandering inductor includes a plurality of first inductors having first lengths and a plurality of second inductors having second lengths shorter than the first lengths, the first inductors and the second inductors being alternatively connected with each other, wherein a region occupied by the meandering inductor is an inductor region; and
a shielding film disposed between the principal surface of the semiconductor substrate and the meandering inductor, the shielding film including a plurality of openings therein entirely through the shielding film, wherein the openings respectively extend from a first side of the inductor region toward an opposite second side of the inductor region and across the first inductors of the meandering inductor.

8. The semiconductor device according to claim 7, wherein the openings are arranged in parallel with each other.

9. The semiconductor device according to claim 7, wherein the shielding film includes one of aluminum and copper.

10. The semiconductor device according to claim 7, wherein the shielding film has at least four of the openings.

11. The semiconductor device according to claim 7, wherein the openings are rectangular.

12. The semiconductor device according to claim 7, further comprising:
a plurality of interconnection films disposed over the principal surface of the semiconductor substrate, wherein the interconnection films are coupled to the semiconductor integrated circuit; and
a polyimide film disposed on the principal surface of the semiconductor substrate so as to cover the interconnection films.

13. The semiconductor device according to claim 7, wherein the shielding film is coupled to a ground voltage.

14. A manufacturing method of a semiconductor device, comprising:
providing a semiconductor substrate including a principal surface;
forming a semiconductor integrated circuit in the principal surface of the semiconductor substrate, wherein a region occupied by the semiconductor integrated circuit is an element region;
forming a shielding film over the element region of the principal surface of the semiconductor substrate, wherein the shielding film includes a plurality of openings which extend from a middle of the element region toward a periphery of the element region; and
forming a spiral inductor on the shielding film formed over the element region, so that the spiral inductor extends across and over the openings of the shielding film and are electrically coupled to the semiconductor integrated circuit.

15. The manufacturing method according to claim 14, further comprising:
forming a plurality of interconnection films over the principal surface of the semiconductor substrate so as to be coupled to the semiconductor integrated circuit; and
forming a polyimide film on the interconnection films so as to cover the interconnection films.

16. The semiconductor device according to claim 14, the shielding film is formed by one of aluminum and copper.

17. A manufacturing method of a semiconductor device, comprising:
providing a semiconductor substrate including a principal surface;
forming a semiconductor integrated circuit in the principal surface of the semiconductor substrate, wherein a region occupied by the semiconductor integrated circuit is an element region;
forming a shielding film over the element region of the principal surface of the semiconductor substrate, wherein the shielding film includes a plurality of openings which respectively extend from a first side of the element region toward an opposite second side of the element region; and
forming a meandering inductor on the shielding film formed over the element region so that the meandering inductor is electrically coupled to the semiconductor integrated circuit, wherein the meandering inductor includes a plurality of first inductors having first lengths and a plurality of second inductors having second lengths shorter than the first lengths, the first inductors and the second inductors being alternatively connected with each other, and wherein the first inductors of the meandering inductor extend across and over the openings of the shielding film.

18. The manufacturing method according to claim 17, further comprising:
forming a plurality of interconnection films over the principal surface of the semiconductor substrate so as to be coupled to the semiconductor integrated circuit; and
forming a polyimide film on the interconnection films so as to cover the interconnection films.

19. The semiconductor device according to claim 17, the shielding film is formed by one of aluminum and copper.
